(19) United States
(12) Patent Application Publication
(10) Pub. No.: US 2024/0316642 A1
(43) Pub. Date: Sep. 26, 2024

(54) CONSTRUCTION METHOD FOR 3D MICRO/NANOSTRUCTURE

(71) Applicant: Henan University, Kaifeng (CN)

(72) Inventors: Guanghong Yang, Kaifeng (CN); Caihong Jia, Kaifeng (CN)

(21) Appl. No.: 18/733,366

(22) Filed: Jun. 4, 2024

Related U.S. Application Data
(63) Continuation of application No. 17/597,858, filed on Jan. 26, 2022.

(51) Int. Cl. B22F 10/366; B22F 12/41; B22F 12/70; B33Y 10/00; B33Y 70/00; B81C 1/00; B82Y 40/00

(52) U.S. Cl. CPC B22F 10/366; B22F 12/41; B22F 12/70; B33Y 10/00; B33Y 70/00; B81C 1/00373; B81C 1/00626; B22F 2201/20; B22F 2302/25; B81C 2201/0183; B82Y 40/00

(57) ABSTRACT

A construction method for 3D micro/nanostructure, comprising: Step (1), fixing and vacuuming a material source on a substrate; Step (2), focusing an electron beam to ensure that a position of a focus is 0-100 nm away from a surface of material source, and an interface local domain including the focus of electron beam and surface atoms is formed; and Step (3), controlling the focus of electron beam to move point by point according to a shape of a designed 3D micro/nanostructure, and realizing the construction of 3D micro/nanostructure. This disclosure realizes real-time construction of 3D micro/nanostructure through the migration of atoms driven by uneven atomic density and electric potential difference in interface local domain. This disclosure promotes integrative development of nanotechnology and 3D printing and has good value of application and promotion.

### CROSS-REFERENCE TO RELATED APPLICATIONS

This application is a Continuation of the U.S. application Ser. No. 17/597,858 filed on Jan. 26, 2022, and entitled “CONSTRUCTION METHOD FOR 3D MICRO/NANOSTRUCTURE”, now pending, the entire disclosures of which are incorporated herein by reference.

### TECHNICAL FIELD

The disclosure relates to a method for construction of a nanostructure, in particular to a construction method for three-dimensional (3D) micro/nanostructure.

### BACKGROUND

In the micro/nanoscale, the motion laws of electrons, photons and phonons of material are limited by its microstructure, this confinement effect of micro/nanostructure makes the material have many novel physical and chemical properties, and have broad application prospects in the fields such as information, material, energy and environment. Therefore, the processing and preparation technology of micro/nanostructured materials has attracted much attention.

In order to accurately control the size, composition and structure of material, a series of synthesis and preparation methods have been developed. Generally it can be divided into two categories: bottom-top and top-bottom methods. The bottom-top methods, such as vapor-liquid-solid chemical vapor deposition, solid-liquid-solid process and self-assembly methods can use inherent properties of materials, such as crystal orientation growth, hydrophilicity and hydrophobicity, to prepare nanomaterials from several angstroms to hundreds of nanometers. These methods have advantages of low cost, convenience and fast preparation, and can provide most basic materials for the construction of nanodevices. However, these bottom-top methods are lack of accurate control of the material structure and size, and complex nanofabrication and assembly processes are required in the later stage in the formation of functional micro/nanodevices. The top-bottom methods, represented by photolithography and electron beam lithography, not only have great advantages in device manufacturing, large-scale integration and addressability, but also achieve great success in the machining accuracy of nanostructures. However, the shortcomings of these technologies are also obvious, such as the cumbersome and complex steps of structure processing process, the need for multi-step graphics transmission process and strict experimental conditions, and the lack of flexibility to modify the design scheme in real time. Obviously, it is not suitable for multifunctional integrated devices composed of a variety of nanomaterials, the electrical interconnection between the basic units of nanosystems and the real-time and high-precision processing of 3D micro/nanostructures, etc.

As a rapid prototyping technology, 3D printing technology can realize the real-time construction of 3D structure with a high aspect ratio. However, most 3D printing technologies, such as Stereolithography (SL), Fused Deposition Modeling process (FDM), Selective Laser Sintering (SLS), selective deposition lamination, etc., have a processing accuracy of more than 100 microns, and are not suitable for the construction of micro/nanostructures. 3D jet printing by Lewis et al., can fabricate silver line electrodes with a linewidth of micron level. However, in the nanoscale, the influence of surface energy is becoming more and more important, the processing accuracy of this jet printing method is affected by the surface energy and the aperture size of the instrument inkjet probe and it is not suitable for the construction of the micro/nanodevices. The 3D laser direct writing technology based on multiphoton absorption polymerization reaction can achieve processing accuracy of 100/200 nm, but the raw materials are mainly limited to organic photosensitive monomer and organic materials, and the direct result is 3D organic polymer micro/nanostructure. In order to realize metal oxide semiconductor devices, complex structure inversion replication processes also required. At present, it is one of the difficulties to find a real-time microfabrication technology that can accurately control the material forming process at the micro/nanoscale and realize the printing and construction of semiconductor 3D micro/nanostructures in materials science, engineering and nanotechnology.

### DISCLOSURE

In order to overcome the shortcomings of existing technologies and methods, the disclosure aims to provide a construction method for 3D micro/nanostructure, and realizes the real-time printing construction of 3D micro/nanostructure, which is of great significance to the development of nanofabrication technology and 3D printing field.

The object of the disclosure is realized by the following technical scheme.

A construction method for 3D micro/nanostructure comprises:
Step (1), fixing a material source on a substrate, and vacuuming the material source on the substrate;
Step (2), focusing an electron beam to ensure that a position of a focus of the electron beam is 0-100 nm away from a surface of the material source, and an interface local domain including the focus of the electron beam and surface atoms is formed;
Step (3), controlling the focus of the electron beam to move point by point according to a shape of a designed 3D micro/nanostructure, and realizing a construction of 3D micro/nanostructure.

Preferably, the material source in the Step (1) may be one of metal elementary substances or compounds composed of metal elements and other non-metallic elements.

Preferably, the material source is one of a block solid, a film, a rod, a powder composed of nanowires, a powder composed of nanoparticles and a powder composed of nanoribbons.

Preferably, the substrate in the Step (1) is made of a conductor material or semiconductor material.

Preferably, a vacuum degree in the Step (1) is 10⁻³-10⁻⁵ Pa.

Preferably, in the Step (2), an acceleration voltage is 1-30 kV, a working distance is 3-20 mm, and a spot size of the electron beam is 1-50 nm.

Preferably, in the Step (3), the point by point movement of the focus of the electron beam can be completed by a displacement platform with an accurate positioning function or a focusing/scanning control program of electron beam. The displacement platform realizes accurate positioning through laser measurement, grating measurement.

Compared with existing technologies and methods, the disclosure has advantageous effects in that: the disclosure relates to a construction method for 3D micro/nanostructure, in which the focus of electron beam is used to activate and control the surface layer atoms of the material source via thermal radiation so as to increase the kinetic energy of the surface atoms, thereby overcoming the constraint of the surface energy to escape from the surface. At the same time, the uneven atomic density and electric potential difference in the interface local domain make the surface atoms of the material source diffuse toward the low-density and low potential energy region. Combined with the grating positioning displacement platform and the corresponding focusing/scanning graphical control program, the real-time construction of 3D structures at micro/nanoscale is realized. The disclosure solves the construction problems of 3D micro/nanostructures in the field of material processing and 3D printing, extends the processing accuracy of 3D printing technology to nanoscale, and promotes the integrative development of nanotechnology and 3D printing, thereby having good values of application and promotion.

### BRIEF DESCRIPTION OF DRAWINGS

FIG. 1 is a schematic view of the construction method for 3D micro/nanostructure in the disclosure;

FIG. 2 is a view of positions of material source (A), electron beam focus (B) and interface local domain (C) during construction;

FIG. 3 is a letter “ED” pattern constructed on the surface of ZnO material in embodiment 1;

FIG. 4 is a view of plant seed germ-like structure constructed on cobalt nickel oxide nanowire in embodiment 2; and

FIG. 5 is a view of a nanorod constructed at the top of a copper wire in embodiment 3.

In the drawings: 1. Electron beam; 11. Electron beam focus; 2. Substrate; 3. Material source; 4. Nanostructure.

### BEST MODE

Hereinafter, the disclosure is further described in combination with the accompanying drawings and specific embodiments. It should be noted that, on the premise of no conflict, the embodiments or technical features described below can be arbitrarily combined to form new embodiments.

### Example 1

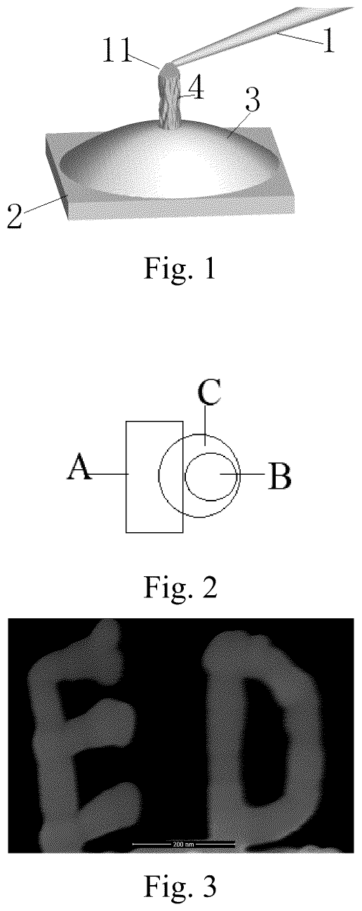

A construction method for 3D micro/nanostructure comprises the following steps.
Step (1), the silicon wafer with length and width of 1 cm were ultrasonically cleaned for ten minutes in ultrapure water, ethanol and acetone in turn and used as substrate 2. A layer of ZnO film with a thickness of 100 nm was deposited on the silicon substrate 2 by magnetron sputtering, and used as material source 3 for constructing the 3D structure. The silicon substrate deposited with the ZnO film was placed into the vacuum chamber of electron microscope to be vacuumed until the vacuum degree reached 10⁻⁴ Pa.
Step (2), the filament was turned on, the state of electron beam 1 and the grating displacement platform was adjusted so that the working distance was 7 mm, the acceleration voltage was 10 kV, the electron beam spot size was 10 nm, and electron beam 1 was obliquely incident on the ZnO surface at an angle of 70° (as shown in FIG. 1), so that the electron beam focus 11 was located at the adjacent position above the ZnO surface and had the distance from the ZnO surface by 10 nm (region B in FIG. 2), and the electron beam focus 11 and ZnO surface layer atoms formed an interface local domain (region C in FIG. 2). The surface atoms in the interface local domain were activated via the thermal radiation of the electron beam focus 11 so that the kinetic energy of the surface atoms increased, and at the same time, the activated atoms on the ZnO surface were diffused toward the focus due to the uneven atomic density and electric potential energy difference in the interface local domain.
Step (3), through the grating positioning displacement platform and the focusing/scanning graphical control program, the focus of the electron beam was controlled to move point by point according to a shape of a designed letter structure to form the corresponding upright ZnO 3D letter, and FIG. 3 shows the nanostructure 4 of “ED” character formed by ZnO atoms.

### Example 2

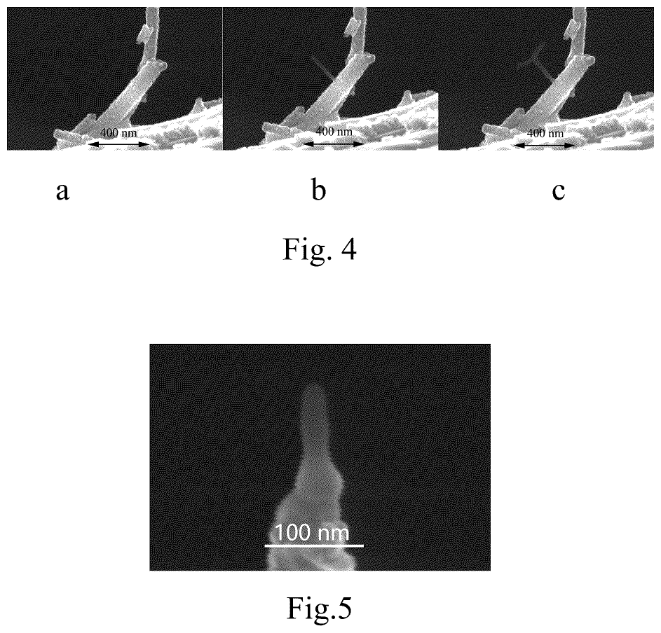

A construction method for 3D micro/nanostructure comprises the following steps.
Step (1), the cobalt nickel hydroxide polycrystalline nanowires were synthesized by hydrothermal method and then annealed in muffle furnace at 400° C. for 2 hours, the cobalt nickel oxide polycrystalline nanowires were dispersed on the silicon wafer substrate as the material source for the growth of nano germ, and the above silicon wafer substrate was placed into the vacuum chamber of the electron microscope to be vacuumed until the vacuum degree reached 10⁻³ Pa.
Step (2), the filament was turned on, the state of electron beam and the grating displacement platform was adjusted so that the working distance was 12 mm, the acceleration voltage was 15 kV, and the electron beam spot size was 20 nm, electron beam was focused so that the focus was located near the growing point of the cobalt nickel oxide polycrystalline nanowire powder and had the distance from the surface of the cobalt nickel oxide polycrystalline nanowire by 0 nm, so that the electron beam focus was tangent to the surface of the nanowire. The interface local domain was formed to include the electron beam focus and the surface layer of the growth point of cobalt nickel oxide polycrystalline nanowires. And the surface atoms in the interface local domain were activated via the thermal radiation of the electron beam focus so that the kinetic energy of the surface atoms increased, and at the same time, the activated atoms on the surface were diffused toward the focus of electron beam due to the uneven atomic density and electric potential energy difference in the interface local domain.
Step (3), through the grating positioning displacement platform and the focusing/scanning graphical control program, the electron beam focus was controlled to move point by point according to the shape of the designed plant seed germ-like structure to form corresponding plant seed germ-like shape. As shown in FIG. 4, a, b and c represent the formation process of germ-like nanostructure, and the complete germ-like nanostructure can be seen in c.

### Example 3

A construction method for 3D micro/nanostructure comprises the following steps.
Step (1), a section of copper wire was pulled with force to break and fixed on a copper sample table with the conductive tape as a substrate, and the broken end of the copper wire was considered as the growing point of a nanorod, and the above copper sample table was placed into the electron microscope vacuum chamber to be vacuumed until the vacuum degree was close to 10⁻⁵ Pa.
Step (2), the filament was turned on, the electron beam state and the grating displacement platform was adjusted so that the working distance was 20 mm, the acceleration voltage was 30 kV, the electron beam spot size was 50 nm, and then the electron beam was focused, so that the electron beam focus was located near the growing point of the copper wire and had the distance from the copper wire growth point by 50 nm, and an interface local domain was formed to include the focus of electron beam and the surface atoms near the growing point of the copper nanorod. The surface copper atoms in the interface local domain were activated via the thermal radiation of the electron beam focus so that the kinetic energy of the surface copper atoms increased, and at the same time, the activated copper atoms on the surface were diffused toward the focus of electron beam due to the uneven atomic density and electric potential energy difference in the interface local domain.
Step (3), through the positioning displacement platform and the focusing scanning program, the focus of electron beam was controlled to move point by point according to the designed shape of nanorod, and a corresponding copper nanorod was formed. As shown in FIG. 5, the diameter of the nanorod is about 25 nm.

The above embodiments are only the preferred embodiments of the disclosure, which cannot limit the scope of protection of the disclosure. Any non-substantive changes and substitutions to be made by those skilled in the field on the basis of the disclosure shall fall within the scope of protection required by the disclosure.

1. A construction method for 3D micro/nanostructure, comprising:
Step (1), fixing a material source on a substrate, and vacuuming the material source on the substrate;
Step (2), focusing an electron beam to ensure that a position of a focus of the electron beam is 0-100 nm away from a surface of the material source in the Step (1), and an interface local domain including the focus of the electron beam and surface atoms is formed; the surface atoms in the interface local domain were activated, and the activated atoms were diffused toward the focus;
Step (3), controlling the focus of the electron beam to move point by point according to a shape of a designed 3D micro/nanostructure, and realizing the construction of 3D micro/nanostructure;
wherein in the Step (2), an acceleration voltage is 1-30 kV, a working distance is 3-20 mm, and a spot size of the electron beam is 1-50 nm.

2. The construction method for 3D micro/nanostructure of claim 1, wherein the material source in the Step (1) comprises one of metal elementary substances, or compounds composed of metal atoms and other non-metallic atoms.

3. The construction method for 3D micro/nanostructure of claim 2, wherein the material source comprises one of a bulk solid, a film, a rod, a powder composed of nanowires, a powder composed of nanoparticles and a powder composed of nanoribbons.

4. The construction method for 3D micro/nanostructure of claim 1, wherein the substrate in the Step (1) is made of a conductor material or a semiconductor material.

5. The construction method for 3D micro/nanostructure of claim 1, wherein a vacuum degree in the Step (1) is 10⁻³-10⁻⁵ Pa.

6. The construction method for 3D micro/nanostructure of claim 1, wherein in the Step (3), the focus of the electron beam is controlled to move point by point according to the designed 3D micro/nanostructure in combination with a displacement platform and a focusing/scanning control program.
